(19) United States
(12) Patent Application Publication
(10) Pub. No.: US 2007/0001696 A1
(43) Pub. Date: Jan. 4, 2007

(54) Electronic device and electronic assembly

(75) Inventors: Jorge Wang, Taoyuan Hsien (TW); Gavin Wang, Taoyuan Hsien (TW); Colin Tsao, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/375,099

(22) Filed: Mar. 15, 2006

(30) Foreign Application Priority Data
Jun. 30, 2005 (TW) 94122150

(51) Int. Cl. G01R 31/02

(52) U.S. Cl. 324/761

(57) ABSTRACT

An electronic device and an electronic assembly are disclosed. The main body of the electronic device has a first surface, a second surface, an accommodating portion, at least one first pin disposed on the first surface, a plurality of second pins disposed on the second surface and at least one coil disposed within the accommodation portion. The coil is connected to the first pin and the second pin, respectively. There is at least a part of the second pins extending forward to the first surface and penetrating through the first surface and the second surface.

### BACKGROUND OF THE INVENTION

The invention relates to an electronic device, and in particular to a modularized and modernized filter.

A surface mount device (SMD) is formed by connecting a plurality of electronic components on a printed circuit board. SMD is a current trend in preparation of electronic devices. An SMD component is attached to the printed circuit board, and a coil is formed by winding copper wires on an iron core which is then manually welded on the solder material located on the printed circuit board. A plurality of pins, which the coil is electronically connected thereto, are inserted in the guide holes of the circuit board, and then the SMD component and the coil are packaged by silicon glue. As the results, the electronic components are integrally packaged on the circuit board.

With the increasing number and density of coils, however, it is difficult to manually weld the coils on the circuit board, thus, reliability and accuracy cannot be easily maintained or even improved.

Further, due to the pins of the coils being manually plugged in, defects, such as biasing leg and incorrect or asymmetric pin length inevitably occur. Additionally, it is difficult to ensure uniform application of silicon glue on the circuit board and to adjust the flow rate of glue during filling processes. Thus, features such as quality and appearance of the electronic products cannot be adequately controlled.

### SUMMARY OF THE INVENTION

The invention provides a modularized and modernized electronic device (e.g. filter).

The electronic device includes a main body. The main body has a first surface, a second surface, an accommodating portion, at least one first pin disposed on the first surface, a plurality of second pins disposed on the second surface and at least one coil disposed within the accommodation portion. The coil is connected to the first pin and the second pin, respectively. There is at least a part of the second pins extending forward to the first surface and penetrating through the first surface and the second surface.

Several coils disposed within the accommodation portion can be arranged in series or parallel. The electronic device can further include an adhesive, a packing material, a resilient material or a soft material disposed in the main body so as to seal the coil in the accommodation portion.

The main body further includes at least one wire organizer or a wire leading slot for guiding and protecting the coil. The number of the wire organizer or wire leading slots is determined by summing up the number of the first pin and the second pin.

The electronic device further includes a circuit unit disposed outside of the first surface. The circuit unit can be connected to the first pin by welding. The circuit unit includes at least one first pin hole corresponding to the first pin and the number of the first pin hole is similar to that of the first pin. Also, the Circuit unit further includes at least one second pin hole corresponding to the part of the second pins for allowing the part of the second pins to pass therethrough. Because the part of the second pins penetrates through the first surface and the second surface, the first surface and the second surface are electrically connected with each other via the part of the second pins. The circuit unit, the first surface and the second surface are substantially arranged in parallel. The main body further includes a protrusion to secure the circuit unit, and the protrusion is relatively protruded from the circuit unit.

The invention further provides an electronic assembly including at least one electronic device and a housing. The electronic device includes a main body having a first surface, a second surface, an accommodating portion, at least one first pin disposed on the first surface, a plurality of second pins disposed on the second surface and at least one coil disposed within the accommodation portion. The coil is connected to the first pin and the second pin rspectively. There is at least a part of the second pins extending forward to the first surface and penetrating through the first surface and the second surface. Due to the protrusion being relatively protruded from the circuit unit when the circuit unit is disposed on the main body, the circuit unit does not contact the main body and the housing when the base plate is fastened to the housing so that damage to the circuit unit from is prevented.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the subsequent detailed description and the accompanying drawings, which are given by way of illustration only, and thus are not limitative of the present invention, wherein:

FIGS. 1 and 2 are schematic views of an electronic device of the first embodiment of the invention.

FIGS. 3 and 4 are schematic views of an electronic assembly of the second embodiment of the invention.

### DETAILED DESCRIPTION OF THE PREFERRED EMBODIMENTS

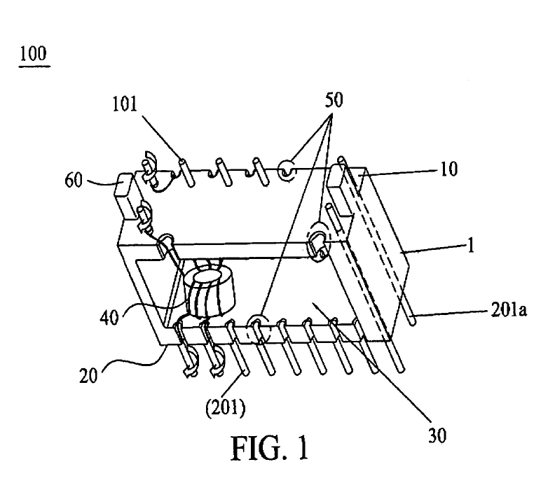

In FIG. 1, an electronic device 100 of the first embodiment of the invention has a main body 1. The main body 1 includes a first surface 10, a second surface 20, an accommodating portion 30, at least one first pin 101 disposed on the first surface 10, a plurality of second pins 201 disposed on the second surface 20, at least one coil 40, a wire organizer or wire leading slot 50, and at least one protrusion 60. There is at least a part 201a of the second pins extending forward to the first surface 10 and penetrating through the first surface 10 and the second surface 20.

The coil 40 has a core wire 401 guided and protected by the wire leading slot 50, and two ends of the core wire 401 are connected to the first pin 101 and the second pin 201 respectively. Because the part 201a of the second pins penetrates through both of the first surface 10 and the second surface 20, the first surface 10 and the second surface 20 are electrically connected with each other via the part 201a of the second pins. The coil 40 disposed within the accommodation portion 30 can be arranged in series or parallel. In addition, an adhesive, a packing material, a resilient material or a soft material can be disposed in the main body 1 so as to seal the coil 40 in the accommodation portion 30. The number of wire leading slot 50 is determined by summing up the number of first pins 101 and the second pins 201. The coil 40 can be connected to the first pin 101 and the second pin 201 by welding, clamping or winding.

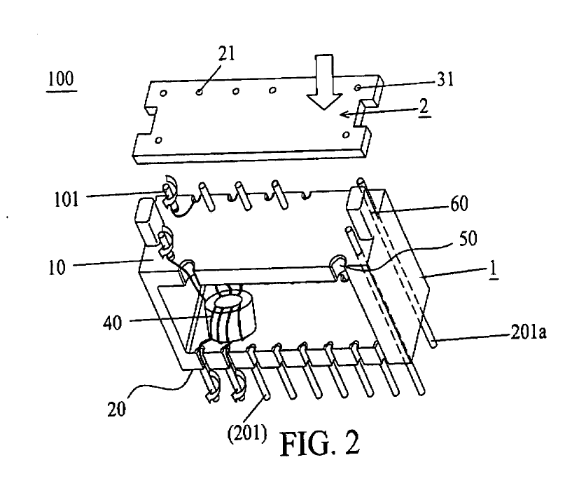

In FIG. 2, the electronic device 100 further includes a circuit unit 2 having a Surface Mount Device (SMD, but not shown in FIGS.) component. The circuit unit 2 is disposed outside of the first surface 10 and connected to the first pin 101 by welding. The circuit unit 2 has at lest one first pin hole 21 and at least one second pin hole 31. The first pin hole 21 is disposed corresponding to the first pin 101, and the number of the first pin hole 21 is similar to that of the first pin 101. Also, the second pin hole 31 is disposed corresponding to the part 201a of the second pins, and the number of the second pin hole 31 is similar to that of the part 201a of the second pins. In FIG. 2, there are two second pins 201a penetrating the first surface 10 and the second surface 20 and passing through two second pin holes 31, respectively. Preferably, the circuit unit 2, the first surface 10 and the second surface 20 are substantially arranged in parallel. The protrusion 60 of the main body 1 is used to secure the circuit unit 2 so that the protrusion 60 is relatively protruded from the circuit unit 2 when the circuit unit 2 is disposed on the main body 1.

Due to the protrusion 60 being relatively protruded from the circuit unit 2 when the circuit unit 2 is disposed on the main body 1, the circuit unit 2 is not contacted by the main body 1 and the housing 210 when the base plate 220 is fastened to the housing 210. As the results, the circuit unit 2 can be prevented from being damaged.

The main body 1 can be made by plastics, metal, alloy, stainless or ceramics. The circuit unit 2 is a preferred printed circuit board, and the electronic device 100 is a filter for LAN or Ethernet.

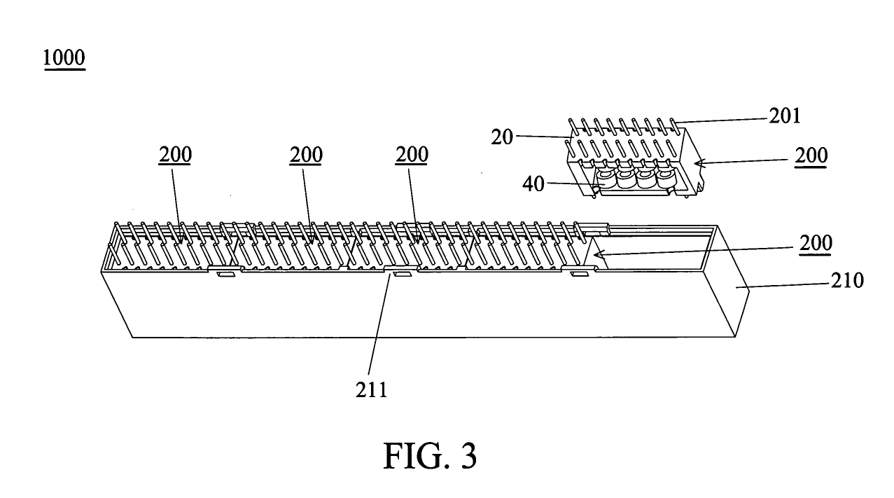

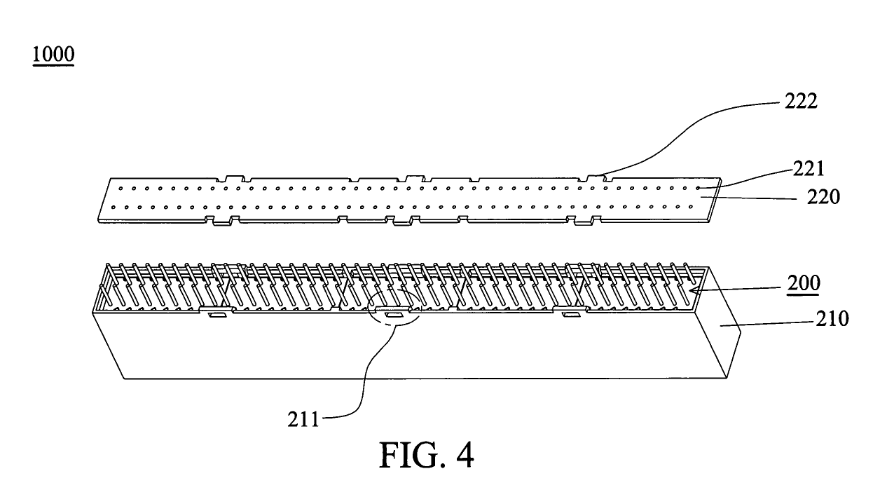

In FIGS. 3 and 4, an electronic assembly 1000 of the second embodiment of the invention includes a plurality of electronic devices 200, a housing 210 and a base plate 220 covering the housing 210. Each electronic device 200 inserted into the housing 210 has the same structure and the corresponding symbols as the electronic device 100 of the first embodiment. It is noted that the electronic devices 200 in FIGS. 3 and 4 are disposed inversely for a clarifying purpose when compared with the electronic device 100 in FIGS. 1 and 2.

The housing 210 has at least one second engaging member 211. The base plate 220 has at least one hole 221 corresponding to the second pin 201 and at least one first engaging member 222 corresponding to the second engaging member 211 of the housing 210. In this embodiment, the first engaging member 222 is a protruding tooth and the second engaging member 211 is indentation. When the first engaging member 222 of the base plate 220 is correspondingly engaged with the second engaging member 211 of the housing 210, the base plate 220 is fastened to the housing 210.

In comparison with the conventional manual solder welding, because the invention provides the wire leading slot 50 for guiding and protecting the coil 40, the first pins 101 and the second pins 201 of the electronic device 100 can be rapidly welded by robot or automatic machine and the ends of the coil 40 can be rapidly welded under a wave soldering process by a general operator, and thus yielding efficiency, reliability and quality of soldering connection can be increased and defects such as biasing leg incorrect or asymmetric pin length can be eliminated.

Additionally, because the electronic assembly is formed by several single electronic devices, the damaged or malfunctioning electronic devices can be easily replaced, i.e., the electronic assembly is easily maintained and repairable. Furthermore, the base plate is mechanically connected to the housing by the engagement of the first engaging member and the second engaging member, instead of the traditional gluing method (e.g. glue dispensing or filling, which easily results in unstable electrical characteristics and cracking) of application. The process of the invention is simplified, and thus quality and yield of the electronic assembly can be increased.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. An electronic device, comprising:
a main body comprising a first surface, a second surface, an accommodating portion, at least one first pin disposed on the first surface, a plurality of second pins disposed on the second surface and at least one coil disposed within the accommodation portion, wherein the coil is connected to the first pin and the second pin, respectively, and at least a part of the second pins extends forward to the first surface and penetrates through the first surface and the second surface.

2. The electronic device as claimed in claim 1, farther comprising a circuit unit disposed outside the first surface.

3. The electronic device as claimed in claim 2, wherein the circuit unit comprises a printed circuit board and the circuit unit is connected to the first pin by welding.

4. (canceled)

5. The electronic device as claimed in claim 2, wherein the circuit unit, the first surface and the second surface are substantially arranged in parallel.

6. The electronic device as claimed in claim 2, wherein the circuit unit comprises at least one first pin hole corresponding to the first pin.

7. The electronic device as claimed in claim 6, wherein the circuit unit further comprises at least one second pin hole corresponding to the part of the second pins for allowing the part of the second pins to pass therethrough.

8. The electronic device as claimed in claim 2, wherein the main body further comprises a protrusion to secure the circuit unit, and the protrusion is relatively protruded from the circuit unit.

9. The electronic device as claimed in claim 1, wherein at least two coils disposed within the accommodation portion are arranged in series or in parallel.

10. The electronic device as claimed in claim 1, further comprising an adhesive, a packing material, a resilient material or a soft material disposed in the main body so as to seal the coil in the accommodation portion.

11. The electronic device as claimed in claim 1, wherein the coil is connected to the first pin and the second pin by welding, clamping, or winding.

12. The electronic device as claimed in claim 1, wherein the main body further comprises at least one wire organizer or wire leading slot for guiding and protecting a core wire of the coil, and the number of the wire organizer or wire leading slot is determined by summing up the number of the first pin and the second pin.

13. The electronic device as claimed in claim 1, wherein the main body comprises plastics, metal, alloy, stainless or ceramics.

14. The electronic device as claimed in claim 1, wherein the electronic device is a filter for LAN or Ethernet.

15. An electronic assembly, comprising:
at least one electronic device comprising a main body comprising a first surface, a second surface and an accommodating portion, at least one first pin disposed on the first surface, one a plurality of second pins disposed on the second surface and at least one coil disposed within the accommodation portion, wherein the coil is connected to the first pin and the second pin, respectively; and
a housing for receiving the unit electronic device;
wherein there is at least a part of the second pins extending forward to the first surface and penetrating through the first surface and the second surface.

16. The electronic assembly as claimed in claim 15, further comprising a base plate covering the housing.

17. The electronic assembly as claimed in claim 16, wherein the base plate comprises of at least one hole corresponding to the second pin.

18. The electronic assembly as claimed in claim 17, wherein the base plate further comprises at least one first engaging member, and the housing comprises at least one second engaging member correspondingly engaged with the first engaging member so that the base plate is fastened to the housing.

19. The electronic assembly as claimed in claim 18, wherein the first engaging member comprises a protruding tooth and the second engaging member comprises an indentation.

20. The electronic device as claimed in claim 1, wherein the part of the second pins penetrates through the first surface and the second surface so that the first surface and the second surface are electrically connected with each other via the part of the second pins.
